(19) United States
(12) Patent Application Publication
(10) Pub. No.: US 2021/0134989 A1
(43) Pub. Date: May 6, 2021

(54) SEMICONDUCTOR DEVICE AND METHOD OF MANUFACTURING THEREOF

(71) Applicant: mqSemi AG, Zug (CH)

(72) Inventors: Munaf RAHIMO, Gaensbrunnen (CH); Iulian NISTOR, Niederweningen (CH); Charalampos Papadopoulos, Lenzburg (CH)

(21) Appl. No.: 17/086,358

(22) Filed: Oct. 31, 2020

(30) Foreign Application Priority Data
Oct. 31, 2019 (GB) 1915864.1

(51) Int. Cl. H01L 29/739; H01L 29/06; H01L 29/10; H01L 29/423

(52) U.S. Cl. CPC H01L 29/7395; H01L 29/4236; H01L 29/1095; H01L 29/0696

(57) ABSTRACT

An Enhanced Planar MOS cell based on a simple and self-aligned process provides a structure where the lateral distance between the edge of the gate electrode opening and the end of the P-well region is less than 70% from the vertical distance between the surface of the substrate and the depth of the P-well region. Usually, for previous designs, this ratio was 70-80% or more. A spacer can be introduced at the edge of the polysilicon gate electrode openings after the diffusion of an enhancement layer. Using the spacer, a P-type implant is made, resulting in a shorter lateral MOS channel, while the vertical depth of the P-well remains unchanged. The design results in much lower on-state losses without affecting the voltage blocking capability of the device. This design offers advantages both in terms of performance and processability and can be applied to both IGBTs and MOSFETs.

### CROSS-REFERENCE TO RELATED APPLICATIONS

The present application claims priority to GB Patent Application No. 1915863.1 filed on 31 Oct. 2019. The entirety of this application is hereby incorporated by reference for all purposes.

### FIELD OF THE INVENTION

The invention relates to the field of power semiconductor devices. Power semiconductor devices that are able to withstand a blocking voltage of several hundred Volts at high current rating are typically implemented as vertical or lateral structures, wherein the semiconductor wafer is based for example on a semiconducting material such as silicon (Si) or silicon carbide (SiC) or diamond or gallium oxide (Ga2O3) or gallium nitride (GaN) or zinc oxide (ZnO). More particularly, this invention relates to a method of manufacturing a power semiconductor device.

### BACKGROUND

FIG. 1 shows a typical planar punch through IGBT structure, with a planar P-type well region (9) for forming both the channel and the main voltage blocking junction. Planar designs in general provide good controllable switching behaviour. However, the device design features a high drainage of minority charge carriers, which results in higher voltage drop in conduction mode, i.e. increased conduction losses. To reduce these losses, enhanced planar designs are used as shown in FIG. 2. The enhancement region (10) provides for a shorter lateral channel, improves the spreading of electrons at the edge of the channel, and enhances the concentration of minority charge carriers at the emitter side. These design features lead to lower voltage drop in conduction mode, i.e. reduced conduction losses.

The basic approach to manufacture such a design is to implant both the N-type enhancement region (10) and P-type well region (9) through an opening in the gate electrode, followed by separate diffusion/activation processes for each implant. In a planar cell, the distance (92) in the lateral direction between the edge of the gate electrode (11) and the end of the P-well region (10) is normally around 70-80% of the diffusion depth in the vertical direction (91) of the P-well region (10), given by the P-type dopant (normally Boron) diffusion rates in the silicon material. This diffusion ratio is the same for the enhanced planar cell that makes simultaneous use of both N-type dopants in region (10), and P-type dopants in region (9).

In such a state-of-the-art enhanced planar MOS cell design, the vertical depth (93) is important for establishing a good voltage blocking capability, while the lateral distance (94) is needed for lowering the on-state losses. Hence, to obtain an improved trade-off, a shorter lateral length (94) resulting in a shorter channel and higher enhancement will be advantageous, while keeping the same vertical depth (93). In other words, a lateral distance (94) which is less than 70% of the vertical depth (93) is required. This can be achieved, but with the addition of more complex, costly processes, which are not self-aligned.

It is thus desirable to find a new planar MOS cell design that can still benefit from the enhanced layer concept, while enabling simple process steps and results in lower conduction/on-state losses.

### SUMMARY

It may be an object of the present invention to provide a power semiconductor device with reduced on-state losses, low drainage of holes, stable gate parameters, improved blocking capability, and good controllability such as an Insulated Gate Bipolar Transistor (IGBT) with improved electrical characteristics.

These objects may be met by the subject matter of the independent claims. Embodiments of the invention are described with respect to the dependent claims.

The problem is solved by the semiconductor device with the characteristics of claim 1.

The inventive power semiconductor device has layers of different conductivity types, which layers are arranged between an emitter electrode on an emitter side and a collector electrode on a collector side, which can be arranged opposite of the emitter side in the case of a vertical power semiconductor, but can also be arranged on the same emitter side in the case of lateral power semiconductors. The layers comprise, at a minimum:
a drift layer of a first conductivity type, which is arranged between the emitter side and the collector side,
a first base layer of a second conductivity type, which is arranged between the drift layer and the emitter electrode,
a source region of the first conductivity type, which is arranged at the emitter side embedded into the first base layer and contacts the emitter electrode, which source region has a higher doping concentration than the drift layer,
a second base layer of the second conductivity type, which is arranged at the emitter side embedded into the first base layer and is situated deeper than the source region, and contacts the emitter electrode, which second base layer region has a higher doping concentration than the first base layer, and is in direct electrical contact to the emitter electrode,
an advanced enhancement layer of the first conductivity type, which is arranged between the drift layer and the first base layer, and completely surrounds the first base layer, which advanced enhancement layer region has a higher doping concentration than the drift layer, but a smaller doping concentration than the source region.

The inventive semiconductor device improves a planar MOS cell in order to gain the advantages of using an advanced enhancement layer in terms of reduced on-state losses, low drainage of holes, stable gate parameters, improved blocking and good controllability.

An exemplary embodiment provides a method of manufacturing a power semiconductor device. The exemplary method includes: forming a first oxide layer on the emitter side of a substrate of a first conductivity type; forming a gate electrode layer with at least one opening on the emitter side on top of the first oxide layer; implanting a first dopant of the first conductivity type into the substrate on the emitter side using the formed gate electrode layer as a mask; diffusing the first dopant into the substrate; introducing a spacer at the edges of the gate electrode layer after the diffusion of the first dopant of the first conductivity type, which spacer can be formed with a dielectric layer such as silicon oxide, silicon nitride or other methods known to experts in the field; implanting a second dopant of a second conductivity type into the substrate on the emitter side; and diffusing the second dopant into the substrate.

The new design offers a wide range of advantages both in terms of performance (reduced losses, improved controllability and reliability), and processability (very good control of the width of the spacer can be achieved) with the potential of applying enhanced layer structures. The inventive design is suitable for full or part stripes but can also be implemented in cellular designs.

The inventive design is also suitable for reverse conducting structures, and can be applied to both IGBTs and MOSFETs based on silicon or wide bandgap materials such as silicon carbide (SiC). In particular, the use of a highly doped region of first conductivity type, manufactured, as per the embodiments of this invention, adjacent to the MOS channel, can be very beneficial in reducing the voltage drop in conduction mode for SiC MOSFET semiconductors.

Those skilled in the art will recognize additional features and advantages upon reading the following detailed description and upon viewing the accompanying drawings.

### BRIEF DESCRIPTION OF THE DRAWINGS

The embodiments of the invention will be explained in more detail in the following text with reference to the attached drawings, in which:

FIG. 1: shows the cross section of a Planar MOS IGBT structure (prior art).

FIG. 2: shows the cross section of an Enhanced Planar MOS IGBT structure (prior art).

FIG. 3: shows the cross section of first embodiment of an Advanced Enhanced Planar MOS IGBT structure according to the invention.

FIG. 4a-4j: show the innovative manufacturing steps of a first exemplary embodiment according to the invention.

FIG. 5: shows the cross section of another embodiment of a Reverse Conducting Advanced Enhanced Planar MOS IGBT structure according to the invention.

FIG. 6: shows the cross section of another embodiment of a Planar-Trench Advanced Enhanced Planar MOS IGBT structure according to the invention.

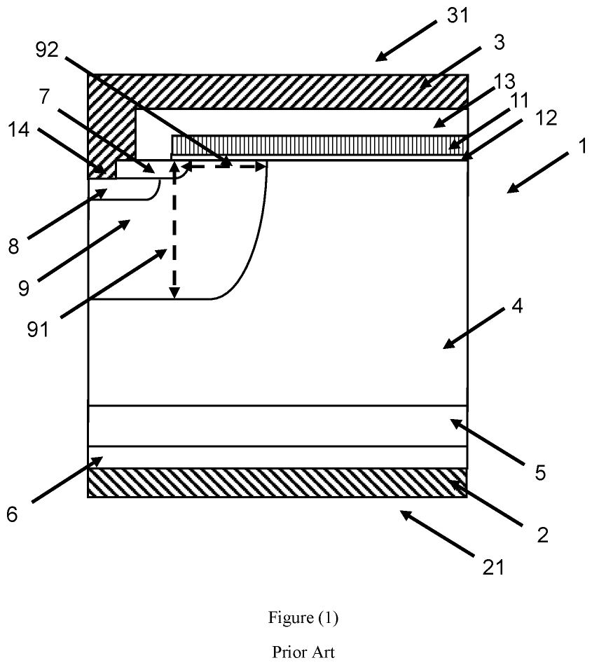

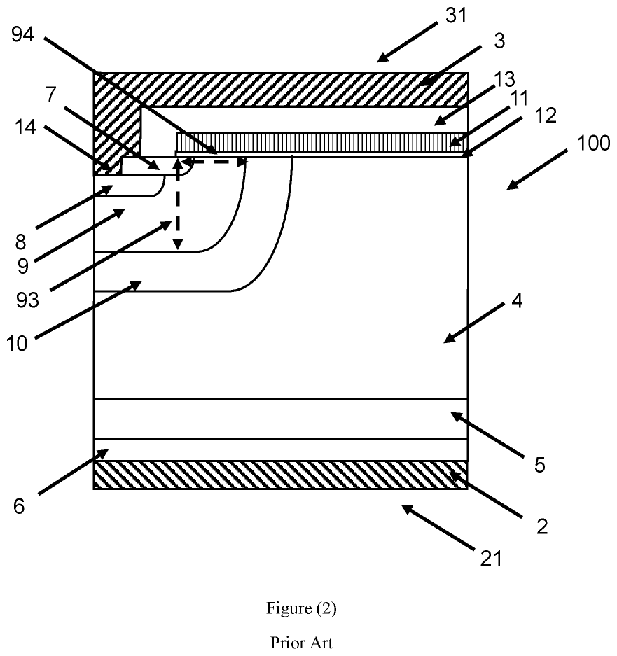

The reference symbols used in the figures and their meaning are summarized in the list of reference symbols. The drawings are only schematically and not to scale. Generally, alike or alike-functioning parts are given the same reference symbols. The described embodiments are meant as examples and shall not confine the invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Reference will now be made in detail to various embodiments, one or more examples of which are illustrated in the figures. Each example is provided by way of explanation, and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appending claims. The drawings are not scaled and are for illustrative purposes only. For clarity, the same elements or manufacturing steps have been designated by the same references in the different drawings if not stated otherwise.

Unless otherwise defined, all terms (including technical and scientific terms) used herein have the same meaning as commonly understood by one of ordinary skill in the art to which example embodiments belong. It will be further understood that terms, e. g., those defined in commonly used dictionaries, should be interpreted as having a meaning that is consistent with their meaning in the context of the relevant art. However, should the present disclosure give a specific meaning to a term deviating from a meaning commonly understood by one of ordinary skill, this meaning is to be taken into account in the specific context this definition is given herein.

In this specification, N-doped is referred to as first conductivity type while P-doped is referred to as second conductivity type. Alternatively, the semiconductor devices can be formed with opposite doping relations so that the first conductivity type can be P-doped and the second conductivity type can be N-doped.

Specific embodiments described in this specification pertain to, without being limited thereto, insulated gate bipolar semiconductor devices.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e. g. “between” versus “directly between”, “adjacent” versus “directly adjacent,” etc.).

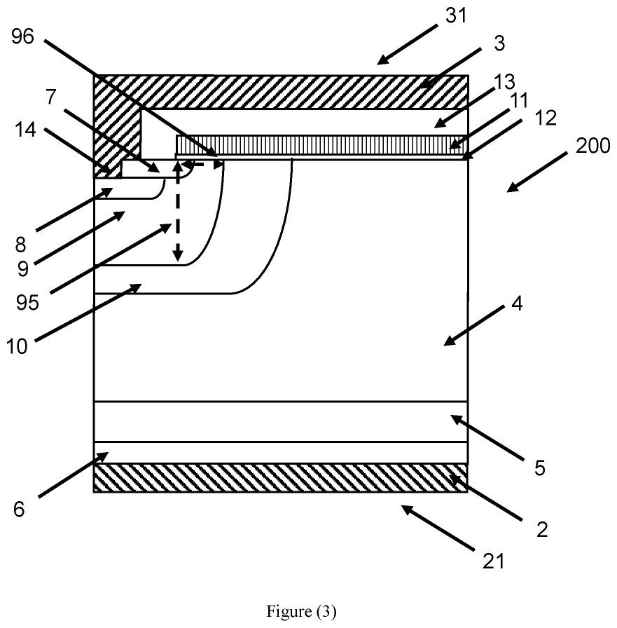

A first exemplary embodiment of a power semiconductor device 200 in form of a punch through insulated gate bipolar transistor (IGBT) with a four-layer structure (pnpn) is shown as cross section representation in FIG. 3. The layers are arranged between an emitter electrode (3) on an emitter side (31) and a collector electrode (2) on a collector side (21), which is arranged opposite of the emitter side (31). The IGBT comprises an N-doped drift layer or substrate (4), which is arranged between the emitter side (31) and the collector side (21), the dopant concentration and thickness of this layer being selected to achieve the blocking voltage the semiconductor device is specified for. The thickness of the drift layer (4) may be for example in the range of several μm to several hundred μm. According to an embodiment, the substrate or drift layer (4) is made of a single crystalline semiconductor material such as Silicon, or a material having a band gap of 2.0 eV or higher such as gallium nitride (GaN) or silicon carbide (SiC).

An additional P-doped first base layer (9) is arranged between the drift layer (4) and the emitter electrode (3), and a second P-doped base layer (8) is arranged between the first base layer (9) and the emitter electrode (3), which second base layer (8) is in direct electrical contact to the emitter electrode (3), and has a higher doping concentration than the first base layer (9). An N-doped source region (7) is arranged at the emitter side (31) embedded into the first base layer (9), and contacts the emitter electrode (3), which source region has a higher doping concentration than the drift layer (4). The second base layer (8) extends perpendicularly deeper than the source region (7).

An advanced enhancement layer (10) of first conductivity type is arranged in the drift layer (4), between the drift layer and the first base (9), in such a manner that the first base layer (9) is embedded in the enhancement layer. The doping concentration of the enhancement layer is larger than the doping concentration of the drift layer (4), but significantly lower than the doping concentration of the source region (7). Main gate electrodes (11) are arranged on the surface of the emitter side (31), and are separated from the drift layer (4) by an electrically insulated layer (12). A lateral MOS channel (not shown) is formable between the emitter electrode (3), the source region (7), the first base layer (9) and the drift layer (4) when positive voltage is applied on the gate electrodes (11). The longitudinal direction of the main gate electrodes (11) is along a first horizontal direction which can be specific to a geometric axis in the starting material or can be randomly selected.

According to a first embodiment, the advanced enhancement layer (10) is formed in such a manner that the vertical maximum depth (95) of the first base layer (9), defined as the maximum distance from the surface of the emitter side to the junction depth between the first base layer and the enhancement layer (10), is substantially the same as the previous maximum depth when using a state-of-the-art enhancement layer. This ensures the blocking capability of the device is largely unchanged. However, the lateral length (96), defined as the distance from the edge of the gate electrode to the junction between the first base layer and the enhancement layer (on the emitter surface), is reduced compared to the same length when using a state-of-the-art enhancement layer. Consequently, the lateral MOS channel length is reduced, and the conduction losses are smaller than with prior art designs.

Further, an interlayer dielectric (13) electrically insulates the emitter electrode (3) from the gate electrodes (11) and may include by way of example one or more dielectric layers from silicon oxide, silicon nitride, silicon oxynitride, doped or undoped silicate glass, for example BSG (boron silicate glass), PSG (phosphorus silicate glass) or BPSG (boron phosphorus silicate glass).

In a first embodiment, a P-doped collector layer (6) is arranged on the collector side (2) in direct electrical contact to the collector electrode (2) and a buffer layer (5) is arranged between the collector layer (6) and the drift region (4). Layers (5) and (6) can also be omitted in other embodiments (i.e. unipolar MOSFET device, non-punch-through power semiconductor devices).

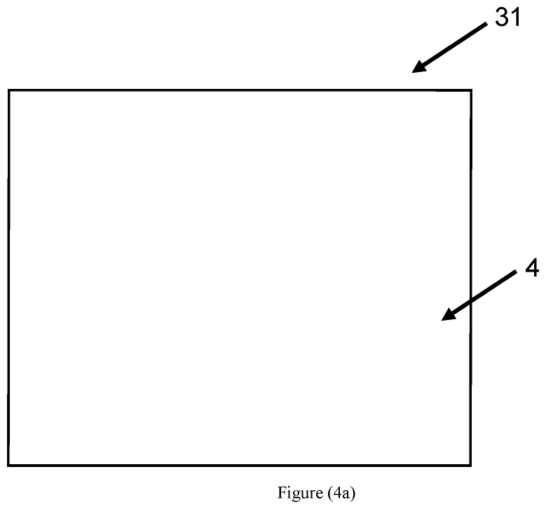

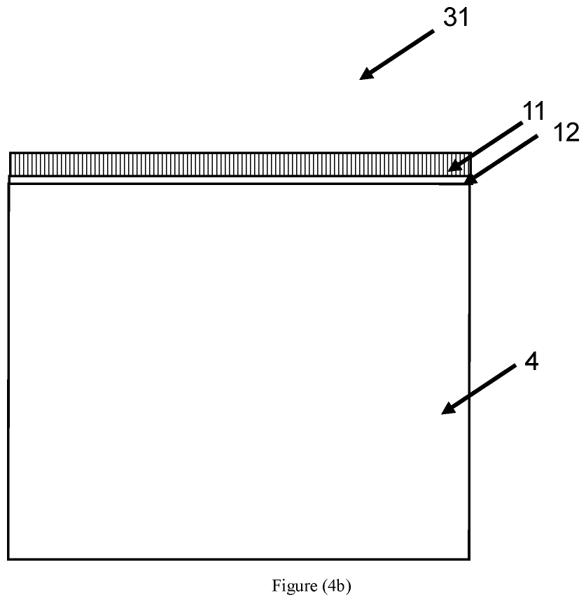

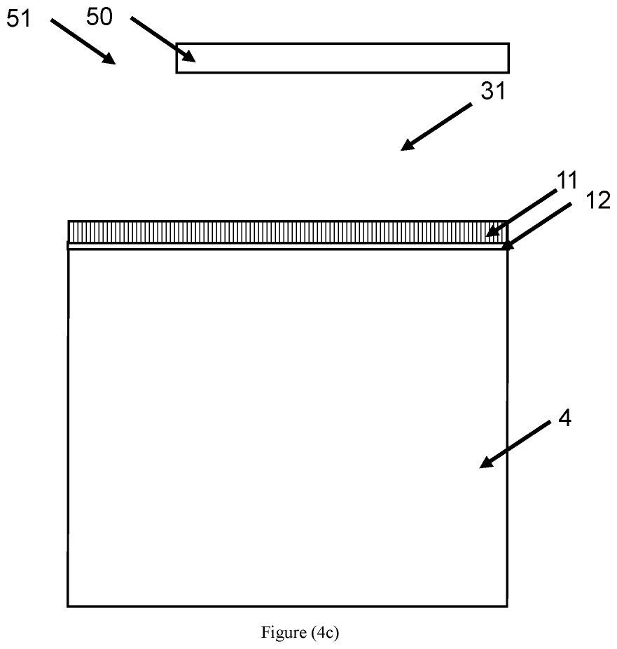

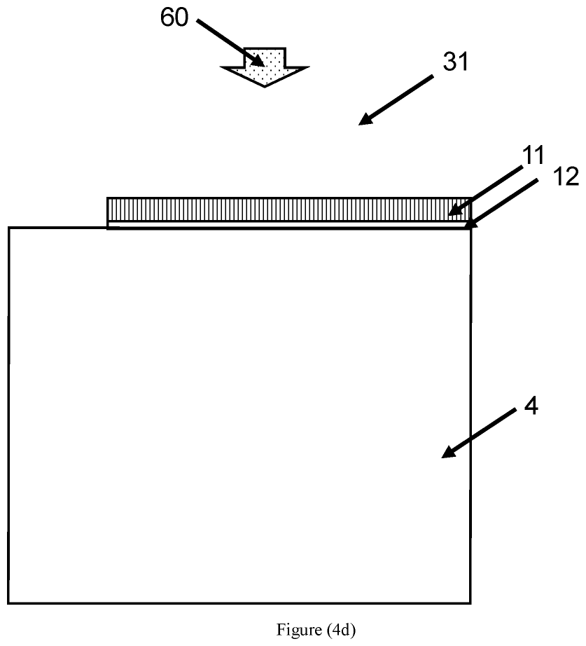

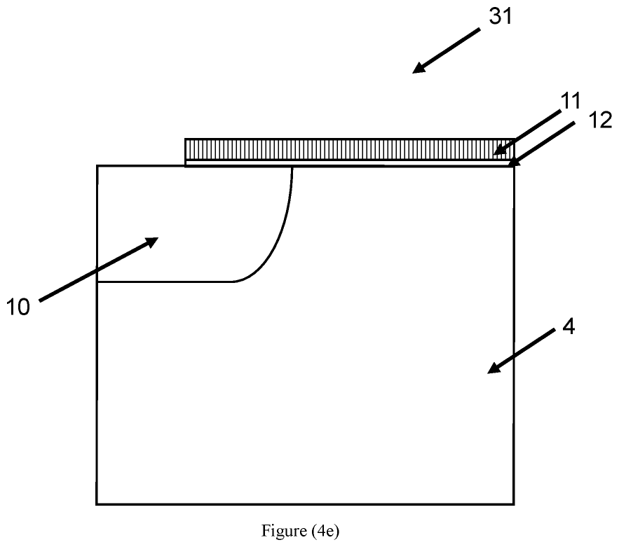

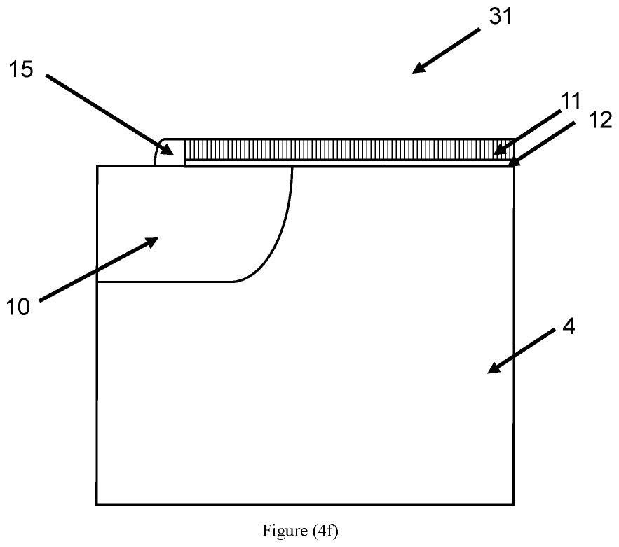

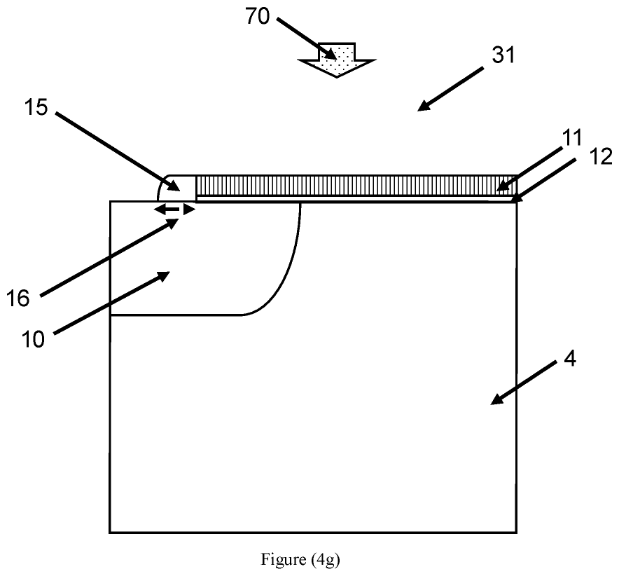

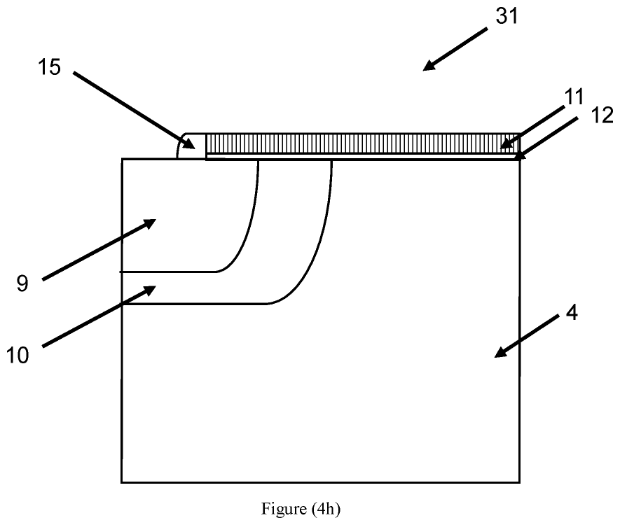

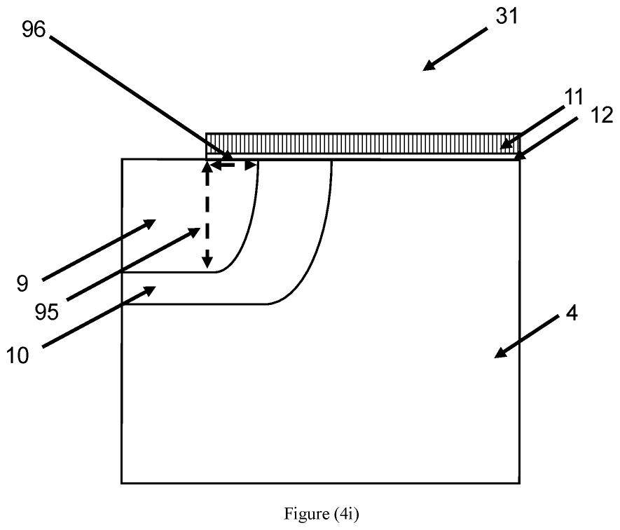

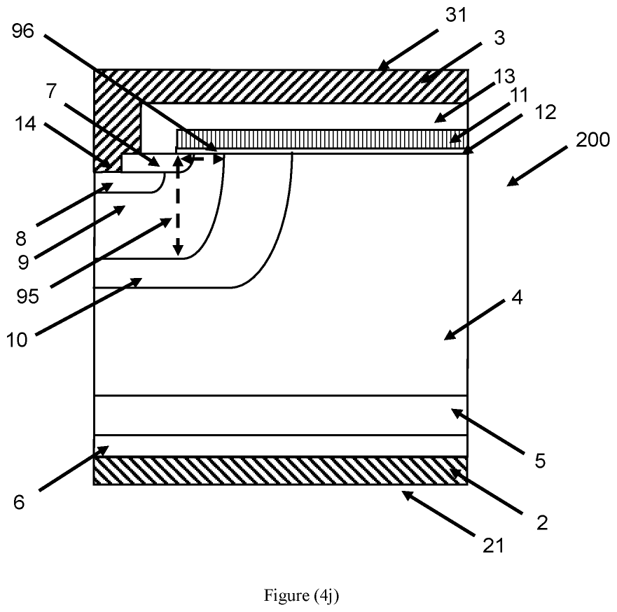

The manufacturing method for a power semiconductor according to the first embodiment includes the following steps:
starting with a substrate (4) of a first conductivity type as shown in FIG. 4(a)
forming a first oxide layer (12) on the emitter side (31) of the substrate (4);
forming a gate electrode layer (11) on the emitter side on top of the first oxide layer (12) as shown in FIG. 4(b); the gate electrode layer can be a highly doped polysilicon layer, or a metal-like layer;
using a mask (50) with openings (51) to form similar openings in the gate electrode layer (11) using etching processes as shown in FIG. 4(c);
implanting a first dopant of the first conductivity type (60) into the substrate (4) on the emitter side, using the formed gate electrode layer with openings as a mask, as represented in FIG. 4(d);
diffusing the first dopant into the substrate and forming the advanced enhancement layer (10) as indicated in FIG. 4(e);
introducing a spacer (15) of precisely controlled width (16) at the edges of the gate electrode layer openings after the diffusion of the first dopant of the first conductivity type as indicated in FIG. 4(f). If the gate electrode is formed with polysilicon material, the spacer is formed by deposition processes (sputtering, chemical or plasma enhanced-vapor deposition, evaporation etc) which does not convert polysilicon during the growth process. If the gate is formed out of a metal like material, an oxidation process could be used as the metal like structure will not be affected during the growth process;
implanting a second dopant of a second conductivity type (70) into the substrate (4) on the emitter side using the spacer (15) and the gate electrode layer as mask, as shown in FIG. 4(g);
diffusing the second dopant into the substrate, and forming the first base layer (9) and the lateral MOS channel, as indicated in FIG. 4(h);
removing the spacer (15) after the second dopant diffusion. Because the gate electrode material was not substantially modified during the deposition process for forming the spacer, it is possible to reconstruct the initial dimension openings (51) in the gate electrode layer, as shown in FIG. 4(i);
implanting the third dopants of first conductivity type and fourth dopants of second conductivity type;
diffusing the third and fourth dopants into the substrate, and forming the source regions (7) and the second base layer (8), respectively;
completing the MOS cell process according to methods known to those skilled in the field, as shown in FIG. 4(j).

The manufacturing method for a power semiconductor according to the second embodiment includes the following steps:
starting with a substrate (4) of a first conductivity type as shown in FIG. 4(a)
forming a first oxide layer (12) on the emitter side (31) of the substrate (4);
forming a gate electrode layer (11) on the emitter side on top of the first oxide layer (12) as shown in FIG. 4(b); the gate electrode layer is a highly doped polysilicon layer;
using a mask (50) with openings (51) to form similar openings in the gate electrode layer (11) using etching processes as shown in FIG. 4(c);
implanting a first dopant of the first conductivity type (60) into the substrate (4) on the emitter side, using the formed gate electrode layer with openings as a mask, as represented in FIG. 4(d);
diffusing the first dopant into the substrate and forming the advanced enhancement layer (10) as indicated in FIG. 4(e);
introducing a spacer (15) of precisely controlled width (16) at the edges of the gate electrode layer openings after the diffusion of the first dopant of the first conductivity type as indicated in FIG. 4(f). The spacer is formed using a dry or wet oxidation process which substantially and locally converts polysilicon of the gate electrode into the oxide of the spacer;
implanting a second dopant of a second conductivity type (70) into the substrate (4) on the emitter side using the spacer (15) and the gate electrode layer as mask, as shown in FIG. 4(g);
diffusing the second dopant into the substrate, and forming the first base layer (9) and the lateral MOS channel, as indicated in FIG. 4(h);
removing the spacer (15) after the second dopant diffusion. Because the gate electrode material was substantially modified during the oxidation process for forming the spacer, it is not possible to recreate the initial openings (51) in the gate electrode layer, and this will slightly change the implantation boundaries of the third and fourth dopants;
implanting the third dopants of first conductivity type and fourth dopants of second conductivity type;
diffusing the third and fourth dopants into the substrate, and forming the source regions (7) and the second base layer (8), respectively;
completing the MOS cell process according to methods known to those skilled in the field, as shown in FIG. 4(j).

The advanced enhancement layer (10) is formed of dopants of first conductivity type, preferably Phosphorous ions. The dopants are preferably implanted with an energy of 20-100 keV and/or a dose of 5×10¹²/cm² to 5×10¹³/cm². The dopants are driven into a maximum depth between 2 μm and 8 μm, in particular between 2 and 6 μm and in particular between 2 and 4 μm. With this enhancement layer, the conduction losses of the semiconductor device are improved.

The second dopants of second conductivity type are implanted into the substrate (4) using the structured gate electrode layer with its opening as a mask. The second dopants are preferably boron ions. The second dopants are preferably implanted with an energy of 20-100 keV and/or a dose of 5×10¹³/cm² to 3×10¹⁴/cm². The second dopants are driven into a maximum depth between 1 μm and 6 μm, in particular between 1 and 3 μm and in particular between 1 and 2 μm. The second dopants are not only driven into the substrate (4) in a direction perpendicular to the surface, but they are spread out laterally.

The third dopants of first conductivity type are is implanted into the substrate (4) using the structured gate electrode layer with its opening as a mask. The third dopants are preferably Phosphorous or Arsenic preferably Arsenic ions. The third dopants are preferably implanted with an energy of 80-160 keV and/or a dose of 1×10¹⁵/cm² to 1×10¹⁶/cm². The third dopants are driven into a maximum depth between 0.5 μm and 1.5 μm, and are mainly driven into the substrate (4) in a direction perpendicular to the surface, but they are only slightly spread out laterally to form the critical source region under the gate oxide (12).

Because the second dopant implant (70) is made after the spacer (15) is formed, a different distance (96) is provided between the edge of the gate electrode and the end of the first base layer (9), compared to state-of-the-art enhancement layer designs. Subsequent to diffusing the first base layer (9), a shorter lateral MOS channel is thus obtained when compared to the corresponding vertical depth (95) of the same first base layer (9). The condition that the lateral distance (96) represents less than 70% of the vertical distance of interest (95) is fulfilled with this design. Without providing the spacer (15), any effort to reduce the distance (96) and thus the MOS channel length would rely on increasing the dose of the first dopant implant (60), or on reducing the diffusion time of the second dopants. In either case, the vertical depth (95) would then be also substantially modified (i.e. shortened) which will drastically reduce the voltage blocking capability of the power semiconductor.

The spacer (15) can be formed with a dielectric layer such as silicon oxide, silicon nitride or other methods known to experts in the field. Depending on the manufacturing method used, the width (16) of the spacer layer (15) can be specifically controlled to very high resolution, even below 100 nm offering a precise control over the characteristics of the lateral MOS channel.

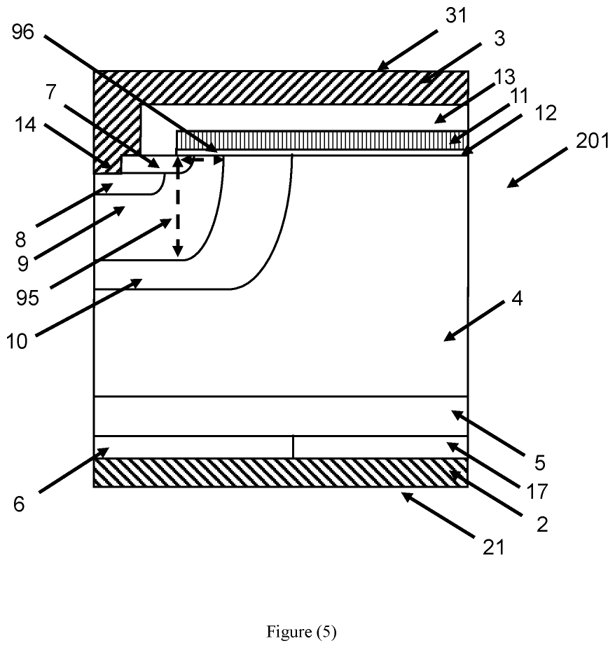

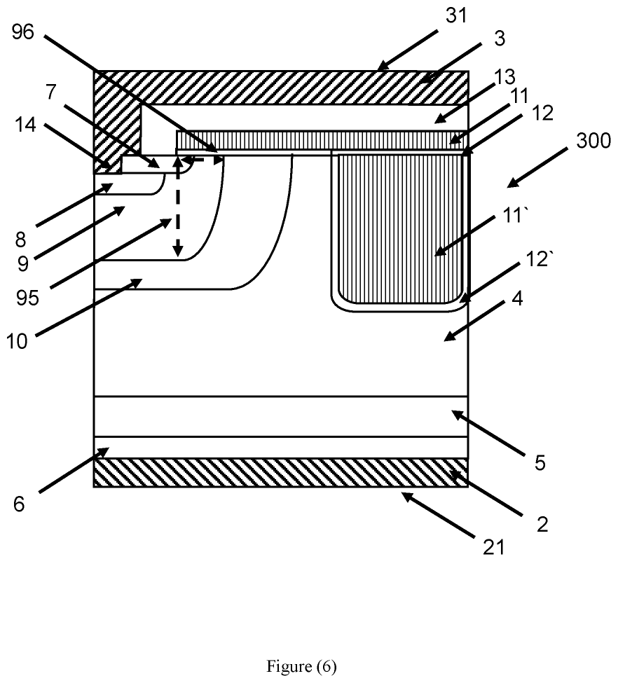

The inventive design is also suitable for a reverse conducting semiconductor device by introducing N-type dopants at the collector side to form the shorts (17) in the P-type collector layer (6), and producing an internal anti-parallel diode structure. This is illustrated in FIG. 5 which schematically shows a cross section of a third embodiment.

In a fourth embodiment, it is possible to apply the same spacer concept to manufacture a cell structure that contains both planar gate electrodes (11) and trench gate electrodes (11), electrically insulated from the drift layer (4) by the insulating layers (12) and (12′) respectively. The advantage of such a planar trench structure resides in achieving an improved minority carrier concentration on the emitter side (31).

According to another embodiment, the planar gate structures (11) can also have a pattern like arrangement on a top view of the surface of the emitter side (31) for example squares, hexagons, octagons or other regular polygons.

It is possible to apply the invention to a method for the manufacturing of semiconductor devices, in which the conductivity type of all layers is reversed, i.e. with a lightly p doped substrate, etc.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

### REFERENCE LIST

1: state-of-the-art planar MOS cell-based power semiconductor device
2: collector metallization (electrode)
21: collector side
3: emitter metallization (electrode)
31: emitter side
4: n-doped drift layer, substrate
5: n-doped buffer layer
6: p-doped collector layer
7: n-doped source layer
8: p-doped second base layer
9: p-doped first base layer
10: n-doped enhancement layer
11: planar gate electrode, electrically conductive layer
11′: trench gate electrode, electrically conductive layer
12: insulating gate oxide for planar gate
12′: insulating gate oxide for trench gate
13: insulation layer for planar cell and trench cell
14: emitter contact opening
15: spacer
16: width of spacer layer;
17: n-doped collector short layer
50: mask to structure openings in the gate electrode layer;
51: openings in the mask (50) translated into openings in the gate electrode layer;
60: implantation of first dopants of first conductivity type;
70: implantation of second dopants of second conductivity type;
91: vertical depth of the first base layer when no enhancement layer is present;
92: lateral length measured from the edge of the gate electrode to the edge of the first base layer;
93: vertical depth of the first base layer surrounded by an enhancement layer;
94: lateral length measured from the edge of the gate electrode to the junction between the first base layer and the enhancement layer (ie. lateral MOS channel length);
95: maximum depth of the first base layer surrounded by an advanced enhancement layer;
96: lateral length measured from the edge of the gate electrode to the junction between the first base layer and the advanced enhancement layer (i.e., lateral MOS channel length);
100: state-of-the-art planar MOS cell-based power semiconductor device with enhancement layer
200: inventive planar MOS cell-based power semiconductor device with an advanced enhancement layer concept
201: inventive reverse conducting planar MOS cell-based power semiconductor device with an advanced enhancement layer concept
300: inventive planar trench MOS cell-based power semiconductor device with an advanced enhancement layer concept

1. A power semiconductor device, comprising:
a substrate or drift layer of first conductivity type, comprising a first main side, a second main side, and a material arranged between the first main side and the second main side, wherein the material comprises Silicon or a wide bandgap material;
a main gate electrode arranged on a surface of the first main side, formed of one or more materials;
a lateral MOS channel formable between a source region, a first base layer, and a drift layer, characterized in that the main gate electrode is insulated from the drift layer by an electrically insulated layer and further characterized in that the main gate electrode has openings and does not uniformly cover the drift layer;
an enhancement layer of a first conductivity type, which is arranged between the drift layer and the first main electrode, wherein the enhancement layer has a higher doping concentration than the drift layer;
the first base layer of a second conductivity type, arranged between the drift layer and a first main electrode and surrounded by the enhancement layer in at least one of a vertical or a lateral direction, characterized in that a distance from an edge of the main gate electrode openings to the end of the first base layer in a lateral direction parallel to the first main side is less than 70% of a maximum depth from the first main side to an end of the first base layer in a vertical direction;
a source region of the first conductivity type, arranged at the first main side embedded into the first base layer, and contacting the first main electrode, characterized in that the source region has a higher doping concentration than the drift layer and the enhancement layer;
a second base layer of the second conductivity type, arranged between the first base layer and the first main electrode, in direct electrical contact to the first main electrode and having a higher doping concentration than the first base layer, wherein the second base layer extends perpendicularly deeper than the source region;
an interlayer dielectric that electrically insulates the first main electrode from the main gate electrode.

2. The power semiconductor device according to claim 1, further comprising:
a plurality of second gate electrodes arranged in trenches vertically etched in the drift layer from a direction of the first main side, characterized in that a lateral MOS channel and a vertical MOS channel connected in series are formable between the source region, the first base layer, and the drift layer when a positive voltage is applied on the main gate electrode and at least one of the plurality of second gate electrode.

3. The power semiconductor device according to claim 1, further comprising:
a buffer layer of the first conductivity type with a higher doping concentration than the drift layer, arranged between the drift layer and a second main electrode.

4. The power semiconductor device according to claim 1, further comprising:
a collector layer of the second conductivity type arranged on the second main side between the drift layer and a second main electrode; or
a buffer layer of the first conductivity type with a higher doping concentration than the drift layer, arranged on the second main side between the drift layer and a second main electrode;
and a collector layer of the second conductivity type arranged on the second main side between the buffer layer and the second electrode.

5. The power semiconductor device according to claim 1, wherein a shorted collector layer, formed by a pattern of opposite conductivity type regions, is arranged at the second main side between a second main electrode and the buffer layer.

6. The power semiconductor device according to claims 1, wherein the device has a stripe layout design or a cellular layout design.

7. A method of manufacturing a power semiconductor device, comprising:
starting with a substrate of a first conductivity type;
forming a first oxide layer on a first main side of the substrate;
forming a gate electrode layer on the first main side on top of the first oxide layer;
using a mask with openings to form similar dimension openings in the gate electrode layer using etching processes;
implanting a first dopant of the first conductivity type into the substrate on the first main side, using the gate electrode layer with openings as a mask, diffusing the first dopant into the substrate, and forming an enhancement layer;
introducing a spacer of a controlled width at edges of the gate electrode layer, characterized in that a material of the spacer is first deposited on the top of the substrate and the gate electrode through a deposition processes that is not dry or wet oxidation;
using another mask to form the spacer using etching processes;
implanting a second dopant of a second conductivity type into the substrate on the first main side using the spacer and the gate electrode layer as masks;
diffusing the second dopant into the substrate, and forming a first base layer and a lateral MOS channel;
removing the spacer after the second dopant diffusion to reconstruct the initial openings in the gate electrode layer using an etching process more specific for the material of the spacer than the material of the gate electrode;
implanting third dopants of the first conductivity type and fourth dopants of the second conductivity type into the substrate;
diffusing the third and fourth dopants into the substrate, and forming source regions and a second base layer, respectively; and
completing forming the MOS cell according to known methods.

8. The method according to claim 7, wherein the spacer is formed of a dielectric layer by means of oxide deposition and etching.

9. The method according to claim 7, wherein the first dopant is implanted with an energy of 20-100 keV and/or a dose of 5×10¹²/cm² to 5×10¹³/cm².

10. The method according to claim 7, wherein the first dopant is diffused into the substrate to a depth of at least 2 μm from an upper surface of the substrate.

11. The method according to claim 7, wherein the second dopant is implanted with an energy of 20-100 keV and/or a dose of 5×10¹³/cm² to 3×10¹⁴/cm².

12. The method according to claim 7, wherein the second dopant is diffused into the substrate to a depth of at least 1 μm from an upper surface of the substrate.

13. The method according to claim 7, wherein the third dopant is implanted with an energy of 80-160 keV and/or a dose of 1×10¹⁵/cm² to 1×10¹⁶/cm².

14. The method according to claim 7, wherein the third dopant is diffused into the substrate to a depth of at least 0.5 μm from an upper surface of the substrate.

15. A method of manufacturing a power semiconductor device, comprising:
starting with a substrate of a first conductivity type;
forming a first oxide layer on a first main side of the substrate;
forming a gate electrode layer on the first main side on top of the first oxide layer;
using a mask with openings to form similar dimension openings in the gate electrode layer using etching processes;
implanting a first dopant of the first conductivity type into the substrate on the first main side, using the formed gate electrode layer with openings as a mask;
diffusing the first dopant into the substrate and forming an enhancement layer;
introducing a spacer of a controlled width at edges of the gate electrode layer openings; characterized in that some of the material of the gate electrode layer is converted into the oxide spacer;
using another mask to form the spacer using etching processes;
implanting a second dopant of a second conductivity type into the substrate on the first main side using the spacer and the gate electrode layer as masks;
diffusing the second dopant into the substrate, and forming a first base layer and a lateral MOS channel;
removing the spacer after the second dopant diffusion using an etching process highly selective for oxide of the spacer and less selective for polysilicon of the gate electrode, characterized in that openings in the polysilicon openings are wider than before forming the spacer;
implanting third dopants of first conductivity type and fourth dopants of second conductivity type into the substrate;
diffusing the third and fourth dopants into the substrate, and forming source regions and a second base layer, respectively;
completing the MOS cell process according to known methods.

16. The method according to claim 15, wherein the first dopant is implanted with an energy of 20-100 keV and/or a dose of 5×10¹²/cm² to 5×10¹³/cm².

17. The method according to claim 15, wherein the first dopant is diffused into the substrate to a depth of at least 2 μm from an upper surface of the substrate.

18. The method according to claim 15, wherein the second dopant is implanted with an energy of 20-100 keV and/or a dose of 5×10¹³/cm² to 3×10¹⁴/cm²; and the second dopant is diffused into the substrate to a depth of at least 1 μm from an upper surface of the substrate.

19. The method according to claim 15, wherein the third dopant is implanted with an energy of 80-160 keV and/or a dose of 1×10¹⁵/cm² to 1×10¹⁶/cm².

20. The method according to claim 15, wherein the third dopant is diffused into the substrate to a depth of at least 0.5 μm from an upper surface of the substrate.
